(19) United States
(12) Patent Application Publication
(10) Pub. No.: US 2013/0056048 A1
(43) Pub. Date: Mar. 7, 2013

(54) WEDGE-SHAPED CARRIER FOR SOLAR CELLS

(71) Applicant: SIKA TECHNOLOGY AG, Baar (CH)

(72) Inventors: Alexander BLEIBLER, Winterthur (CH); Heinz MEIER, Zurich (CH); Hans ROHRER, Sachseln (CH)

(73) Assignee: SIKA TECHNOLOGY AG, Baar (CH)

(21) Appl. No.: 13/652,125

(22) Filed: Oct. 15, 2012

Related U.S. Application Data
(63) Continuation of application No. PCT/EP2011/056043, filed on Apr. 15, 2011.

(30) Foreign Application Priority Data
Apr. 15, 2010 (EP) 10160049.2

(51) Int. Cl. H01L 31/048; H01L 31/0203

(52) U.S. Cl. 136/251; 136/259

(57) ABSTRACT

A photovoltaic system including a wedge-shaped carrier and at least one solar cell. The photovoltaic system has an intermediate space for means for electrically connecting the at least one solar cell.

### RELATED APPLICATIONS

This application claims priority as a continuation application under 35 U.S.C. §120 to PCT/EP2011/056043, which was filed as an International Application on Apr. 15, 2011 designating the U.S., and which claims priority to European Application No. 10160049.2 filed in Europe on Apr. 15, 2010. The entire contents of these applications are hereby incorporated by reference in their entireties.

### FIELD

Disclosed is a photovoltaic system comprising a wedge-shaped carrier as well as at least one solar cell.

### BACKGROUND INFORMATION

Solar cells can be applied to roofing membranes using adhesives. This type of attachment can be undesirable because the solar cells can become detached from the roofing membranes, for example, due to mechanical stresses, and cavities can form in between. The subsequent penetration of moisture into these cavities can have a disadvantageous effect on the joining of the solar cell and the roofing membrane, for example, as a result of damage to the adhesives, and it can promote further detachment. Furthermore, such an attachment may not be suitable for uneven substrates.

The fact that the adhesive can be exposed to outside influences, such as climate and UV radiation, can cause damage to the adhesive over time due to these influences, and as a result the joining can be further weakened.

An additional problem of a comparative system is that, for example, the solar cell is applied directly to the roofing membrane, for example, by gluing, and is consequently exposed. As a result, the solar cell and a device for electrical connection thereof can be exposed to a considerable extent to mechanical stresses which can lead to damage during manufacture, transport, installation or use of the membrane.

The solar cell and a device for electrical connection thereof, as a result of this type of attachment, are located in the immediate vicinity of the roofing membrane, wherein they can be to a considerable extent in contact with water that can collect on the roofing membrane, which can result in stringent desired specifications on the water tightness of solar cells and of a device for electrical connection thereof. Furthermore, once the solar cells are installed, it can be difficult to remove them from the roofing membrane, which can be a disadvantage in the case of repair work.

### SUMMARY

According to an exemplary aspect, disclosed is a photovoltaic system, comprising: a wedge-shaped carrier, and at least one solar cell, wherein the photovoltaic system comprises structure defining an intermediate space for a device for electrical connection of the at least one solar cell.

### BRIEF DESCRIPTION OF THE DRAWING

Exemplary embodiments are further explained in reference to the drawings.

FIG. 1A shows a cross section through a photovoltaic system, according to an exemplary aspect.

FIG. 1B shows a side view of a wedge-shaped carrier with side openings and with openings facing the substrate, according to an exemplary aspect.

FIG. 2 shows a side view of a wedge-shaped carrier, according to an exemplary aspect.

FIG. 3A shows a side view of a wedge-shaped carrier as well as a backside of a solar cell, according to an exemplary aspect.

FIG. 3B shows a spring clamp which is suitable as connecting means for a friction locking connection between the wedge-shaped carrier and the solar cell, according to an exemplary aspect.

FIGS. 3C and 3D show a side view of a friction locking connection between the wedge-shaped carrier and the solar cells of different size by means of a spring clamp, according to an exemplary aspect.

FIG. 4A shows a diagrammatic representation of the connecting means 6b on the bottom side of a wedge-shaped carrier or of a barrier layer, according to an exemplary aspect.

FIG. 4B shows a side view of a wedge-shaped carrier, according to an exemplary aspect.

FIG. 4C shows a perspective side view of a wedge-shaped carrier, according to an exemplary aspect.

FIG. 5 shows a view of the bottom side of a wedge-shaped carrier, according to an exemplary aspect.

FIG. 6 shows a view of a protective jacket which leads away from a wedge-shaped carrier, for the means for electrical connection, according to an exemplary aspect.

### DETAILED DESCRIPTION

According to an exemplary aspect, provided is a photovoltaic system which, for example, can minimize the detachment of solar cells applied to roofing membranes, and can provide better protection of the solar cell and the device electrical connection thereof from mechanical stresses and strains, and from moisture.

According to an exemplary aspect, a photovoltaic system is provided which comprises a wedge-shaped carrier as well as at least one solar cell, which has an intermediate space for the device for electrical connection of the at least one solar cell.

For example, the solar cell and the means for electrical connection, which in a comparative embodiment can be susceptible to damage due to liquids, can be protected from such liquids, for example, since they are not connected by the wedge-shaped carrier directly to the substrate, which, for example, can be a roof or a roofing membrane. For example, as a result, contact with liquid that has collected on the substrate can be reduced or prevented. Furthermore, the wedge shape of the carrier can result in efficient drainage of moisture and dirt from the surface of the solar cell. In addition, the intermediate space can protect the device for electrical connection from outside influences, such as climate, UV radiation, for example, moisture as well as from mechanical stresses and strains. Furthermore, the wedge shape of the carrier can allow an alignment of the solar cells with the angle of incidence of the sunlight, for example, on flat roofs. An additional exemplary benefit is that the wedge-shaped carrier can be used as an uncoupling element for mechanical stresses between the solar cell and the substrate caused by horizontal and vertical displacement of the solar cell and the substrate against each other, for example, of a roofing membrane or the like, caused, for example, by different thermal coefficients of longitudinal expansion.

In an exemplary embodiment, the photovoltaic system, due to the wedge-shaped carrier, can have a smaller area of exposure to wind power, compared to systems with elevated mounting. For example, as a result, the anchoring of the photovoltaic system can be less elaborate, and, for example, it can be possible to dispense with an additional loading of the system or an anchoring in the substrate which can be undesirable, for example, on roofs, as a result of penetration through the roof membrane.

In an exemplary embodiment, the wedge-shaped carrier can comprise resilient materials, which are capable of satisfactorily compensating for the mentioned mechanical stresses. For example, the resilient materials can adapt to uneven substrates caused by overlapping of roofing membranes.

In an exemplary embodiment, a photovoltaic system can be applied efficiently and in a simple manner on already existing substrates, for example, existing roofs.

In an exemplary embodiment, the solar cell can be detachably connected to the wedge-shaped carrier and/or the wedge-shaped carrier can be detachably connected to the substrate. For example, as a result, in the case of repair, the solar cell can be detached from the carrier, or the wedge-shaped carrier can be detached from the substrate, which can make it possible to carry out installation and repair work easily and rapidly.

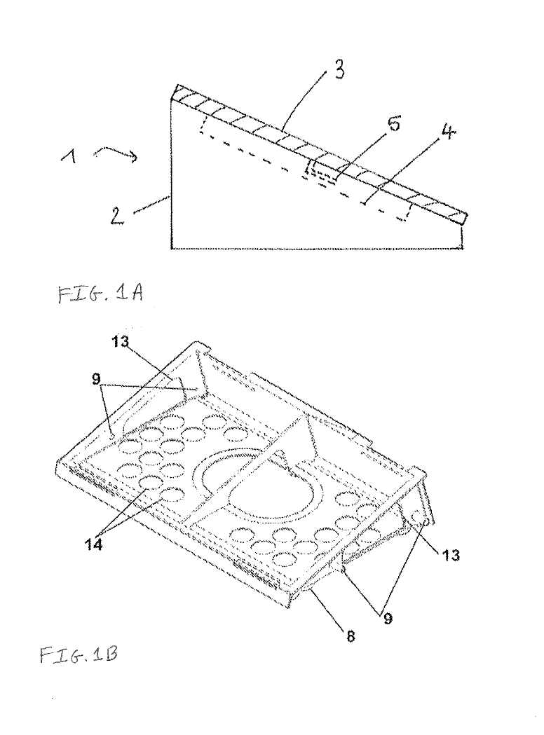

In an exemplary embodiment shown in FIG. 1A, a photovoltaic system 1 comprising a wedge-shaped carrier 2 as well as at least one solar cell 3 is represented, wherein the photovoltaic system has an intermediate space 4 for the device for electrical connection 5 of the at least one solar cell 3.

The term “wedge-shaped” includes a body, wherein two faces converge forming an acute angle, for example, an angle of 3-45°, for example, 3-30°, for example, 3-20°, wherein one face is directed towards the solar cell, and the other face towards the substrate.

The term “solar cell” includes both an individual solar cell unit and a plurality of mutually electrically and/or mechanically connected solar cell units. Exemplary solar cell units are commercially available, for example, from BP Solar, Germany, or Sharp Solar, Germany.

The mentioned solar cell units can have an enclosure made of glass or metal, and they can be enclosed in a plastic layer, which protects them from moisture.

An intermediate space 4 can be formed by the wedge-shaped carrier 2 and the solar cell 3. The intermediate space 4 can be arranged at the exit of the device for electrical connection 5 from the solar cell.

In an exemplary embodiment, the intermediate space is closed off liquid-tight, for example, in order to prevent rainwater from penetrating from the outside into the intermediate space.

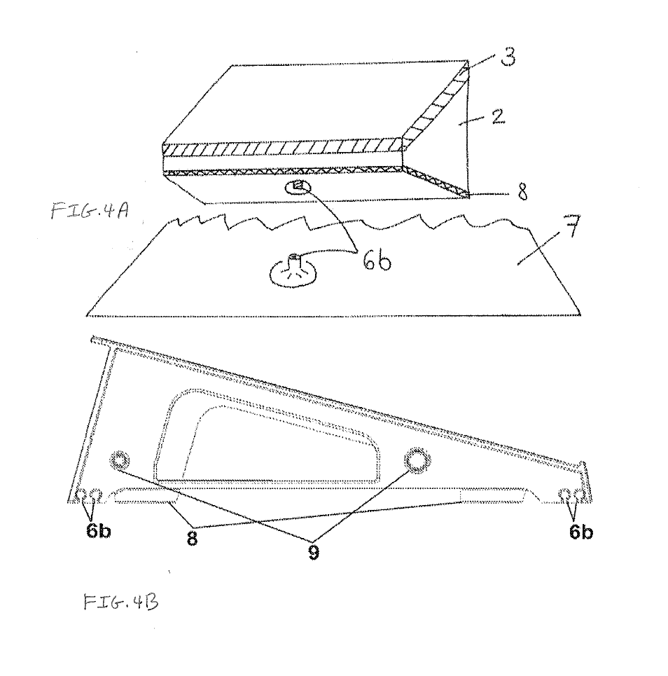

In an exemplary embodiment, the intermediate space has side openings and/or openings on the side facing the substrate as shown, for example, in FIGS. 1B and 4C.

For example, such side openings 13 can be located in the two trapezoid-/wedge-shaped sides of the wedge-shaped carrier. The side openings 14 can reduce the passage of wind, and therefore can decrease the mechanical stresses and strains caused by wind power. Each side opening 13 can cover more than 20%, for example, more than 30% of the surface of each trapezoid-/wedge-shaped side of the wedge-shaped carrier. Such side openings 13 can be seen, for example, in FIGS. 1B, 4B and 4C.

For example, the openings 14 in the wedge-shaped carrier facing the substrate can be beneficial in that they can allow water that has penetrated into the intermediate space 4 to drain off. The resilient material 8 can be beneficial for the drainage. It can be arranged on the surface facing the substrate, and it can cover only a portion of the bottom side of the wedge-shaped carrier 2, for example, less than 25% of the bottom side of the wedge-shaped carrier.

The openings 14 can also be used as passage sites for mechanical connecting means. For example, in this case, after such a use, the opening can still be such that it can be used to allow water to drain off. Otherwise, for example, a sufficient number of such openings can be available and, at least 2, for example, at least 4, openings which are not occupied by mechanical connecting means can be available for water drainage. If the wedge-shaped carrier has more than 4, for example, more than 8, openings 14, a simplified application of the wedge-shaped carrier on the substrate can be possible, for example, in the case of the application with mechanical connecting means, because suitable connection sites can be selected with respect to the substrate, which contributes to a flexible installation. Therefore, in an exemplary embodiment, several openings 14 can be arranged parallel to each other. The wedge-shaped carrier can have more than 2, for example, more than 4 openings 14. Such openings 14 can be seen, for example, in FIGS. 1B and 4C.

In an exemplary embodiment, the intermediate space 4 can have side openings 13 and openings 14 on the side facing the substrate, as shown, for example, in FIGS. 1B and 4C. This embodiment can comprises resilient material 8, which is arranged on the surface facing the substrate, and which covers only a portion of the bottom side of the wedge-shaped carrier 2, for example, less than 25% of the bottom side of the wedge-shaped carrier. This can also be seen, for example, in FIGS. 1B and 4C.

The intermediate space can be arranged at least 5 cm, for example, at least 10 cm, above the substrate. For example, as a result, the device for electrical connection 5 can be protected from liquid that has collected on the substrate.

In an exemplary embodiment, in the intermediate space 4, additional means for electric regulation 10 of the device for electrical connection 5 can be arranged.

For example, fire prevention means, for example, mineral fibers or flame resistant materials, can be arranged in the intermediate space.

For example, means for loading the photovoltaic system, such as mineral material, for example, crushed rock, gravel and/or sand, can be arranged in the intermediate space. If the size of the intermediate space and the quantity/density of the means are sufficient for loading, it is possible to dispense with a connection of the photovoltaic system to the substrate. Therefore, the volume of the intermediate space can be more than 80%, for example, more than 95% of the volume of the wedge-shaped carrier 2.

For example, the volume of the means for loading can be more than 10%, for example, more than 30% of the volume of the intermediate space.

In an exemplary embodiment, the at least one solar cell 3 can be connected via a connecting means 6a to the wedge-shaped carrier 2. The connecting means 6a can be, for example, an adhesive layer.

An adhesive used in such an adhesive layer can be, for example, a pressure sensitive adhesive and/or a melt adhesive. This can ensure a good joining and a good adhesion of the surfaces of the solar cell 3 to the wedge-shaped carrier 2.

Exemplary pressure sensitive adhesives and melt adhesives are described, for example, in CD Römpp Chemie Lexikon, Version 1.0, Georg Thieme Verlag, Stuttgart.

Such an adhesive can be an adhesive selected from ethylene/vinyl acetate copolymer (EVA), olefin-based crosslinkable thermoplastic elastomers, acrylate compounds, polyurethane polymers, and silane-terminated polymers.

Exemplary acrylate compounds can include acrylate compounds based on acrylic monomers, for example, acrylic and methacrylic acid esters.

The term “polyurethane polymer” can include all polymers that are produced by the so-called isocyanate polyaddition method. This can include polymers which are nearly or entirely free of urethane groups. Examples of polyurethane polymers include polyether polyurethanes, polyester polyurethanes, polyether polyureas, polyureas, polyester polyureas, polyisocyanurates, and polycarbodiimides.

Exemplary adhesives are available commercially under the name SikaLastomer®-68 from Sika Corporation, USA.

For example, the at least one solar cell 3 can be detachably connected via the connecting means 6a to the wedge-shaped carrier 2.

This can provide an exemplary benefit, for example, that a chemical connection of the solar cell 3 to the wedge-shaped carrier 2 by means of adhesives can be dispensed with, which can allow a simple and rapid installation and/or disassembly of the solar cell.

The connecting means 6a can be a positive locking connection and/or a friction locking connection.

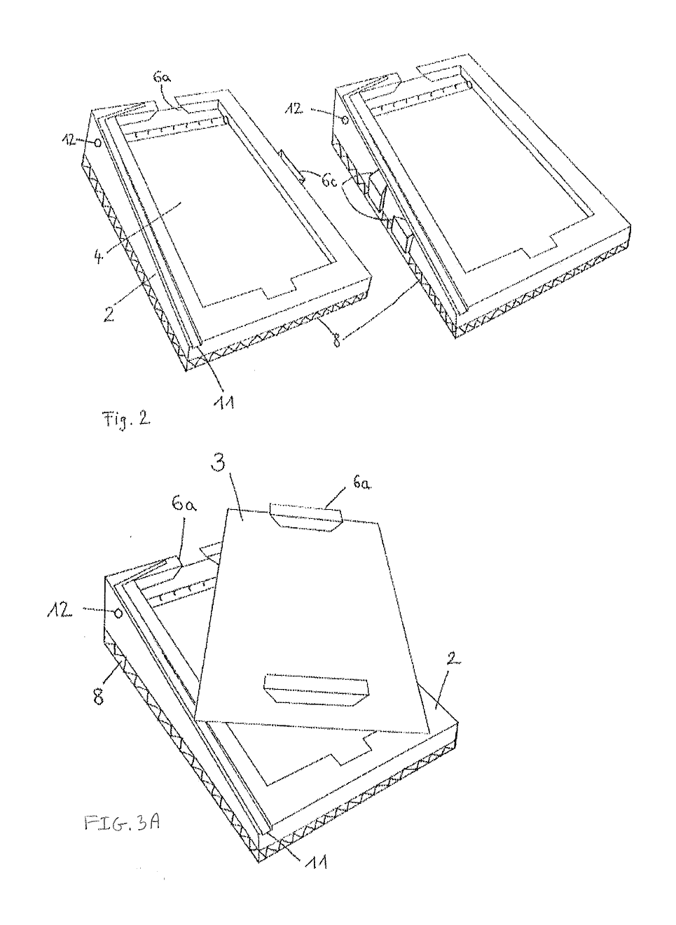

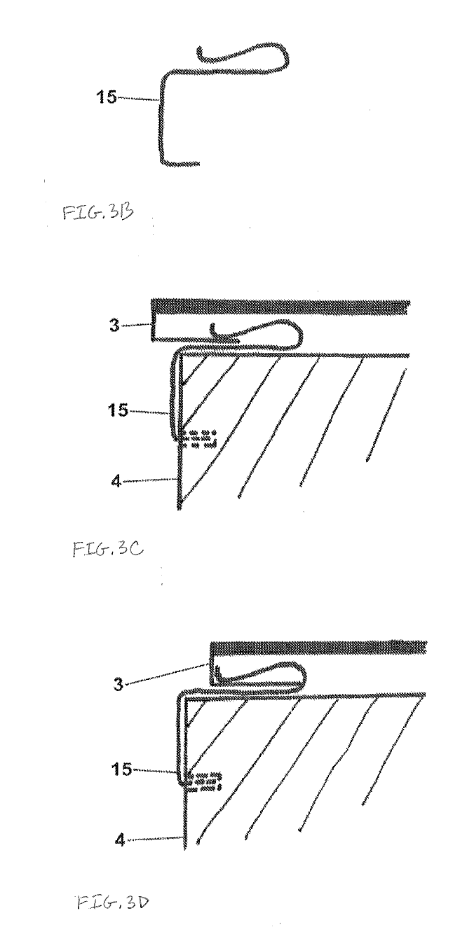

The connecting means 6a can be a positive locking connection, for example, a dovetail, bayonet or groove-spring connection, for example, a dovetail connection, as can be seen in, for example, FIGS. 2 and 3. In FIG. 2, a wedge-shaped carrier is shown, which has a groove as connecting means, and in FIG. 3, the bottom side of a solar cell is shown additionally, which has a spring as connecting means, which fits in the groove of the wedge-shaped carrier.

Such plug connections can provide an exemplary benefit that, leaving the connecting means the same, the shape, size and type of the solar cell can be varied, and a good joining to the wedge-shaped carrier can be attained.

An exemplary connecting means 6a is a friction locking connection, for example, a clamp connection. The connecting means can be, for example, a spring clamp connection. An exemplary spring clamp 15 is shown, for example, in FIGS. 3B, 3C and 3D. A spring clamp can enable a connection between wedge-shaped carriers and solar cells with great flexibility with regard to size differences between the respective components. This can be seen, for example, in FIGS. 3C and 3D. Such a connection type can allow a rapid connection without the use of any tools. Such a connection type can have an excellent ability to compensate for mechanical stresses between the solar cell and the wedge-shaped carrier by horizontal displacement against each other, for example, stresses which are caused by different thermal coefficients of longitudinal expansion.

For example, the wedge-shaped carrier 2 can have a barrier layer 7 on the side facing away from the at least one solar cell 3.

The barrier layer 7 can be made of any materials, for example, that ensure sufficient leak tightness even at high liquid pressure.

The barrier layer 7 can have a high resistance to water pressure and weathering, as well as good values in tear propagation tests and in perforation tests, which can be beneficial if there are mechanical stresses and strains at the building site. For example, resistance to ongoing mechanical stresses and strains, for example, wind, can be provided.

The barrier layer 7 can have a thermoplastic layer, for example, a layer made of thermoplastic polyolefins or polyvinyl chloride (PVC), for example, a layer made of polypropylene (PP) or polyethylene (PE), for example, made of polypropylene. This can result in a high resistance to environmental influences.

The barrier layer 7 can be selected from materials such as high density polyethylene (HDPE), medium density polyethylene (MDPE), low density polyethylene (LDPE), polyethylene (PE), polyvinyl chloride (PVC), ethylene/vinyl acetate copolymer (EVA), chlorosulfonated polyethylene, olefin-based thermoplastic elastomers (TPE-O, TPO), ethylene propylene diene rubber (EPDM) and polyisobutylene (PIB), as well as and mixtures thereof.

The barrier layer 7 can have a thickness of 0.5-8 mm, for example, 1.5-5 mm, for example, 1.2-2 mm.

The wedge-shaped carrier 2 can be connected via a connecting means 6b to the barrier layer 7.

The wedge-shaped carrier 2 can be detachably connected via the connecting means 6b to the barrier layer 7.

This can provide an exemplary benefit, for example, that one can dispense with a chemical connection by means of adhesives. This can enable a simple and rapid installation and/or disassembly of the wedge-shaped carrier.

The connecting means 6b can be a screw connection, for example, a connection with a center screw and a counter piece with inner thread, as can be seen in FIG. 4, for example. For example, FIG. 4 shows the bottom side of the wedge-shaped carrier which has a center screw by means of which a strong connection to the counter piece with inner thread of the barrier layer can be ensured.

For example, the connecting means 6b can be a positive locking connection, for example, a dovetail, bayonet or groove-spring connection, for example, a dovetail connection, as can be seen, for example, in FIGS. 4B and 4C. FIG. 4B shows a wedge-shaped carrier which has, as connecting means, at the front and the rear end of its faces facing the substrate, in each case 2 mutually parallel grooves. Using counter pieces attached to the barrier layer, for example, 2 strips each with 2 parallel spring elements, the wedge-shaped carriers can be installed in a simple and reversible manner.

The barrier layer 7 can be a barrier layer which is applied directly on the substrate, for example, a roofing membrane, or a flat layer, for example, having a larger area than the bottom side of the wedge-shaped carrier, which itself is applied to the roofing membrane or the like. An exemplary benefit of the latter is that such flat layers can be prefabricated and applied subsequently everywhere on roofing membranes or the like, by gluing or welding, for example. Punching through the roofing membrane applied on the substrate with mechanical connecting means for securing the photovoltaic system can be consequently avoided, which can have a beneficial effect on the water tightness of the roofing membrane.

For example, the wedge-shaped carrier 2 can have a water drain 11, as can be seen, for example, in FIG. 2. This can be beneficial in that moisture collecting between the wedge-shaped carrier and solar cell or penetrating from outside can be removed efficiently from the photovoltaic system. For example, it does not penetrate into the intermediate space 4, for example, if the intermediate space is closed off liquid-tight.

The water drain 11 can be arranged at the contact site between the wedge-shaped carrier and the solar cell. The water drain 11 can be designed in such a manner that its opening to the outside presents as small as possible an area for attack by the wind. For example, the cross-sectional area of its opening is 1-10 cm².

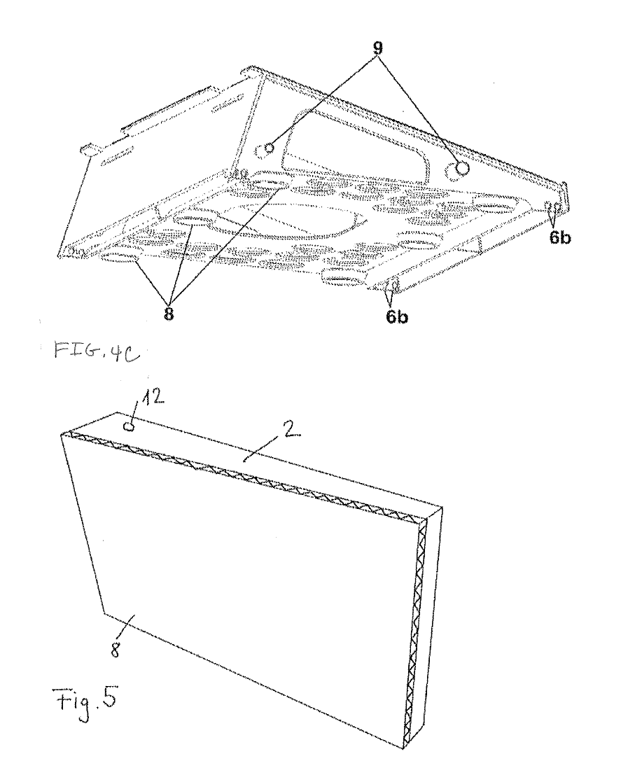

For example, the wedge-shaped carrier 2 can comprise a resilient material 8, as can be seen, for example, in FIG. 5. Mechanical stresses between the solar cell 3 and the substrate can be compensated thereby. An additional exemplary benefit can result from the adaptability of resilient materials to uneven substrates.

The wedge-shaped carrier 2 can be made entirely or partially of the resilient material 8. The wedge-shaped carrier 2 can have a resilient material on the surface facing the substrate, as can be seen in FIG. 5.

The resilient material 8 can be arranged on the surface facing the substrate, and cover only a portion of the bottom side of the wedge-shaped carrier 2, for example, less than 25% of the bottom side of the wedge-shaped carrier. The resilient material can be arranged in such a manner that a stable bracing of the wedge-shaped carrier on the substrate is ensured; for example, there is resilient material at least in the area of the corners of the resilient carrier facing the substrate. Furthermore, the thickness of the resilient material can be at least 5 mm, for example, 10 mm. The effect of this can include that water can drain efficiently out of the intermediate space 4, if the intermediate space is an intermediate space that has openings on the side facing the substrate. FIG. 4B and FIG. 4C show an example of a resilient material which covers a portion of the bottom side of the wedge-shaped carrier 2.

An exemplary embodiment is one that uses the resilient material 8 described as above (for example, resilient material 8, which is arranged on the surface facing the substrate, and which covers only a portion of the bottom side of the wedge-shaped carrier 2), wherein the intermediate space 4 has side openings 13 and openings 14 on the side facing the substrate. This can result in an exemplary combination of a small area of exposure to wind load, and it can allow water that has penetrated into the intermediate space to drain off efficiently. The water that has been removed efficiently can, for example, have no detrimental effect on the solar cell and on the means for electrical connection. For example, the resilient material 8 can provide, for example, the above-mentioned benefits of additionally reducing mechanical stresses between the solar cell 3 and the substrate, and improving the adaptability to uneven substrates. This is shown, for example, in FIGS. 1B and 4C. The resilient material can be in direct contact with the substrate or the barrier layer.

For example, as resilient material, materials can be used which are capable of compensating for stresses by horizontal and vertical displacement of the photovoltaic system and the substrate against each other, which are caused, for example, by the different thermal coefficients of longitudinal expansion of the two.

The resilient material 8 can be selected from, for example, a thermoplast that is solid at room temperature and a thermoplastic elastomer that is solid at room temperature.

The term “room temperature” denotes a temperature of 23° C. Thermoplastic elastomers can provide the benefit of good resilience with respect to horizontal and vertical displacements.

Thermoplastic elastomers can include plastics which combine the mechanical properties of vulcanized elastomers with the processability of thermoplasts. For example, such thermoplastic elastomers can include block copolymers with hard and soft segments, or so-called polymer alloys with corresponding thermoplastic and elastomer components.

Exemplary thermoplasts and thermoplastic elastomers can be selected from polyvinyl chloride (PVC), polyethylene (PE), low density polyethylene (LDPE), ethylene/vinyl acetate copolymer (EVA), polybutene (PB); olefin-based thermoplastic elastomers (TPE-O, TPO) such as ethylene propylene diene/propylene copolymers; olefin-based crosslinked thermoplastic elastomers (TPE-V, TPV); thermoplastic polyurethanes (TPE-U, TPU), such as TPU with aromatic hard segments and polyester soft segments (TPU-ARES), polyether soft segments (TPU-ARET), polyester and polyether soft segments (TPU-AREE), or polycarbonate soft segments (TPU-ARCE); thermoplastic copolyesters (TPE-E, TPC), such as TPC with polyester soft segments (TPC-ES), polyether soft segments (TPC-ET) or with polyester and polyether soft segments (TPC-EE); styrene block copolymers (TPE-S, TPS), such as styrene/butadiene block copolymer (TPS-SBS), styrene/isoprene block copolymer (TPS-SIS), styrene/ethylene-butylene/styrene block copolymer (TPS-SEBS), styrene/ethylene-propylene/styrene block copolymer (TPS-SEPS); and thermoplastic copolyamides (TPE-A, TPA).

The resilient material 8 can be a foamed composition.

The term “foamed composition” includes a structure made of spherical or polyhedral pores, for example, that are delimited by ridges and form a cohesive system.

Pores can include cavities caused by manufacturing in and/or on the surface of a composition which are filled with air or other composition-extraneous substances. The pores may be visible with the naked eye or not. They can be open pores, which are in connection with the surrounding medium, or closed pores, which are closed off and do not allow medium to enter. A mixed form of open and closed pores can also be present. A closed-pore composition can be desirable in that no moisture can enter.

Furthermore, the foamed composition can have a pore size of 0.1-3 mm, for example, 0.2-1 mm and/or a pore volume of 5-99%, for example, 30-98%. Pore volume denotes the percentage proportion of the totality of the cavities filled with air or other composition-extraneous substances with respect to the volume of the foamed composition.

Closed-pore foamed compositions, for example, those having a pore size of less than 1 mm, can be exemplary due to their higher mechanical strength.

The resilient material 8 can have a density of 0.02-1.2 g/cm³, for example, 0.03-0.8 g/cm³, for example, 0.05-0.5 g/cm³.

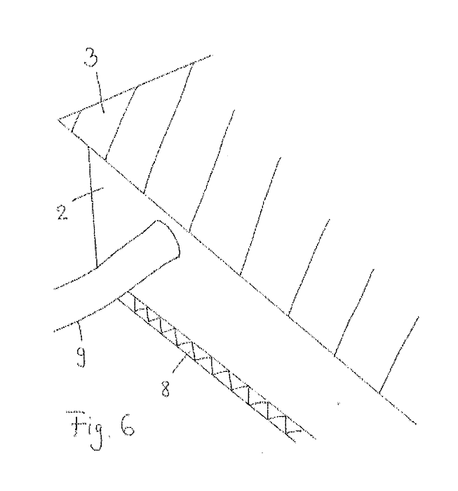

For example, the photovoltaic system can have at least one protective jacket 9 leading away from the wedge-shaped carrier 2, for the device for electrical connection 5, as can be seen, for example, in FIG. 6. This can be desirable in that, as a result, the means for electrical connection, which otherwise can be susceptible to damage caused by liquids and mechanical stresses and strains, can be protected from same.

For example, the protective jacket 9 can be in connection with the intermediate space 4. Openings 12 in the wedge-shaped carrier for the protective jacket can be seen, for example, in FIGS. 2, 3 and 5.

For example, due to its exposure to weathering, the protective jacket 9 as well as the resilient material 8 can involve UV-resistant, rot-resistant, permanently resilient and fire resistant materials.

For example, the wedge-shaped carrier 2 can have a mechanical connecting means 6c which allows a connection to an additional wedge-shaped carrier. This is shown, for example, in FIG. 2. The connecting means 6c can be a positive locking connection, for example, a dovetail, bayonet or groove-spring connection, for example, a dovetail connection, as can be seen, for example, in FIG. 2. Such a connecting means 6c can allow a great flexibility of arrangement of photovoltaic systems on substrates.

For example, the protective jacket 9 can be a portion of the wedge-shaped carrier 2, for example, made of the same material. The protective jacket can be designed in such a manner that it can be used at the same time as mechanical connecting means 6c, in order to connect two adjacent photovoltaic systems to each other, for example, by a plug connection. This can be seen, for example, in FIGS. 1B, 4B and 4C. For example, protective jackets 9 are shown which have a smaller and a larger diameter and whose diameters allow a positive locking plug connection. For example, this arrangement can allow a parallel arrangement and connection of two photovoltaic systems, wherein the protective jacket with the smaller diameter can form a positive locking plug connection to the corresponding protective jacket of the adjacent photovoltaic system. For example, the protective jacket 9 can additionally allow a positive locking plug connection with a laterally adjacent wedge-shaped carrier 2, for example, it can be used as the mechanical connecting means 6c.

For example, the exterior side of the photovoltaic system can present hardly any surface of exposure to wind, for example, it has no or few openings accessible to wind, for example, the intermediate space can be closed off liquid-tight.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE NUMERALS

1 Photovoltaic system
2 Wedge-shaped carrier
3 Solar cell
4 Intermediate space
5 Device for electrical connection
6a Connecting means
6b Connecting means
6c Connecting means
7 Barrier layer
8 Resilient material
9 Protective jacket
10 Means for electrical regulation
11 Water drain
12 Opening for protective jacket
13 Side opening
14 Opening facing the substrate
15 Spring clamp

What is claimed is:

1. A photovoltaic system, comprising:
a wedge-shaped carrier, and
at least one solar cell,
wherein the photovoltaic system comprises structure defining an intermediate space for a device for electrical connection of the at least one solar cell.

2. The photovoltaic system according to claim 1, wherein the at least one solar cell is connected by a connecting means to the wedge-shaped carrier.

3. The photovoltaic system according to claim 2, wherein the at least one solar cell is detachably connected via the connecting means to the wedge-shaped carrier.

4. The photovoltaic system according to claim 2, wherein the connecting means is a positive locking or friction locking connection.

5. The photovoltaic system according to claim 1, further comprising a barrier layer connected to the wedge-shaped carrier on a side facing away from the at least one solar cell.

6. The photovoltaic system according to claim 5, wherein the wedge-shaped carrier is connected via a connecting means to the barrier layer.

7. The photovoltaic system according to claim 6, wherein the wedge-shaped carrier is detachably connected to the barrier layer.

8. The photovoltaic system according to claim 6, wherein the connecting means is a screw connection.

9. The photovoltaic system according to claim 6, wherein the connecting means is a positive locking connection.

10. The photovoltaic system according to claim 1, wherein the wedge-shaped carrier comprises a water drain.

11. The photovoltaic system according to claim 1, wherein the wedge-shaped carrier comprises a resilient material.

12. The photovoltaic system according to claim 11, wherein the resilient material is selected from the group consisting of a thermoplast that is solid at room temperature and a thermoplastic elastomer that is solid at room temperature.

13. The photovoltaic system according to claim 11, wherein the resilient material is a foamed material.

14. The photovoltaic system according to claim 1, wherein the photovoltaic system comprises at least one protective jacket leading away from the wedge-shaped carrier, for the device for electrical connection.

15. The photovoltaic system according to claim 11, wherein the resilient material is arranged on the surface of the wedge-shaped carrier facing the substrate, and it covers only a portion of the surface, and the intermediate space includes side openings and openings on the side facing the substrate.

16. The photovoltaic system according to claim 8, wherein the screw connection is a connection with a center screw and a counter piece with an inner thread.

17. The photovoltaic system according to claim 9, wherein the positive locking connection is a dovetail connection.

18. The photovoltaic system according to claim 1, wherein the solar cell includes a plurality of electrically and/or mechanically connected solar cell units.

19. The photovoltaic system according to claim 13, wherein the foamed material has a pore size of 0.1-3 mm and a pore volume of 5-99%.

20. The photovoltaic system according to claim 1, further comprising the device for electrical connection of the at least one solar cell.
